(19) United States
(12) Patent Application Publication
(10) Pub. No.: US 2022/0216842 A1
(43) Pub. Date: Jul. 7, 2022

(54) ACOUSTIC WAVE DEVICE AND FILTER DEVICE

(71) Applicant: Murata Manufacturing Co., Ltd., Nagaokakyo-shi (JP)

(72) Inventors: Sho NAGATOMO, Nagaokakyo-shi (JP); Tetsuya KIMURA, Nagaokakyo-shi (JP); Takashi YAMANE, Nagaokakyo-shi (JP); Katsuya DAIMON, Nagaokakyo-shi (JP); Takuya KOYANAGI, Nagaokakyo-shi (JP); Yuji TOYOTA, Nagaokakyo-shi (JP)

(21) Appl. No.: 17/704,859

(22) Filed: Mar. 25, 2022

Related U.S. Application Data
(63) Continuation of application No. PCT/JP2020/036416, filed on Sep. 25, 2020.

(30) Foreign Application Priority Data
Sep. 27, 2019 (JP) 2019-177326

(51) Int. Cl. H03H 9/02; H03H 9/13; H03H 9/17; H03H 9/56

(52) U.S. Cl. CPC H03H 9/02086; H03H 9/02031; H03H 9/02228; H03H 9/132; H03H 9/568; H03H 9/175; H03H 9/176; H03H 9/562; H03H 9/564; H03H 9/174

(57) ABSTRACT

An acoustic wave device includes a piezoelectric layer, at least one pair of electrodes adjacent to each other, and an additional film. The piezoelectric layer is made of lithium niobate or lithium tantalate, and includes first and second opposing principal surfaces. The at least one pair of electrodes is located on the first principal surface of the piezoelectric layer. The additional film is located on the piezoelectric layer or either one or both of the electrodes so as to overlap, in plan view, either one or both of areas in which the electrodes are located and an area between the electrodes. When d represents a thickness of the piezoelectric layer and p represents a center-to-center distance between the electrodes, d/p is equal to or less than about 0.5.

### CROSS REFERENCE TO RELATED APPLICATIONS

This application claims the benefit of priority to Japanese Patent Application No. 2019-177326 filed on Sep. 27, 2019 and is a Continuation Application of PCT Application No. PCT/JP2020/036416 filed on Sep. 25, 2020. The entire contents of each application are hereby incorporated herein by reference.

### BACKGROUND OF THE INVENTION

### 1. Field of the Invention

The present invention relates to an acoustic wave device including a piezoelectric layer made of lithium niobate or lithium tantalate, and a filter device including the acoustic wave device.

### 2. Description of the Related Art

In the related art, a known acoustic wave device uses plate waves propagating through a piezoelectric film formed of LiNbO₃ or LiTaO₃. For example, Japanese Unexamined Patent Application Publication No. 2012-257019 described below discloses an acoustic wave device using Lamb waves which are plate waves. In the acoustic wave device, an IDT electrode is disposed on the upper surface of a piezoelectric film formed of LiNbO₃ or LiTaO₃. A voltage is applied between multiple electrode fingers connected to a first potential of the IDT electrode and multiple electrode fingers connected to a second potential. This causes Lamb waves to be excited. Reflectors are disposed on both sides of the IDT electrode. Thus, the acoustic wave resonator using plate waves is formed.

### SUMMARY OF THE INVENTION

In the acoustic wave device described in Japanese Unexamined Patent Application Publication No. 2012-257019, the number of electrode fingers may be reduced for a reduction in size. However, a reduction of the number of electrode fingers causes the Q value to decrease, and also causes difficulty in adjusting the frequency.

Preferred embodiments of the present invention provide acoustic wave devices and filter devices, each of which improve the Q value and easily adjust the frequency even when the size is reduced.

A first preferred embodiment of the present invention provides an acoustic wave device including a piezoelectric layer, a first electrode and a second electrode, and an additional film. The piezoelectric layer is made of lithium niobate or lithium tantalate. The first electrode and the second electrode face each other in the direction intersecting the thickness direction of the piezoelectric layer. The additional film is disposed on the piezoelectric layer or on at least one of the first electrode or the second electrode so as to overlap, in plan view, at least one of a first area or a second area. The first area includes areas in which the first electrode and the second electrode are located. The second area is an area between the first electrode and the second electrode. The acoustic wave device uses primary thickness-shear mode bulk waves.

A second preferred embodiment of the present invention provides an acoustic wave device including a piezoelectric layer, a first electrode and a second electrode, and an additional film. The piezoelectric layer is made of lithium niobate or lithium tantalate. The first electrode and the second electrode face each other in the direction intersecting the thickness direction of the piezoelectric layer. The additional film is located on the piezoelectric layer or on at least one of the first electrode or the second electrode so as to overlap, in plan view, at least one of a first area or a second area. The first area includes areas in which the first electrode and the second electrode are located. The second area is an area between the first electrode and the second electrode. The first electrode is adjacent to the second electrode, and d/p is equal to or less than about 0.5 where d represents a thickness of the piezoelectric layer, and p represents a center-to-center distance between the first electrode and the second electrode.

A third preferred embodiment of the present invention provides a filter device including at least one serial arm resonator and at least one parallel arm resonator. At least one of the at least one serial arm resonator is the acoustic wave device according to the first preferred embodiment of the present invention or the second preferred embodiment of the present invention of the present application, and at least one of the at least one parallel arm resonator is the acoustic wave device according to the first preferred embodiment of the present invention or the second preferred embodiment of the present invention of the present application. The thickness of the additional film of the at least one serial arm resonator is different from the thickness of the additional film of the at least one parallel arm resonator.

Acoustic wave devices and filter devices according to preferred embodiments of the present invention improve the Q value and adjust the frequency easily even when the size is reduced.

The above and other elements, features, steps, characteristics and advantages of the present invention will become more apparent from the following detailed description of the preferred embodiments with reference to the attached drawings.

### BRIEF DESCRIPTION OF THE DRAWINGS

FIGS. 1A and 1B are a schematic perspective view of the appearance of an acoustic wave device according to a first preferred embodiment of the present invention, and a plan view of the electrode structure on a piezoelectric layer.

FIG. 2 is a cross-sectional view of a portion along A-A line in FIG. 1A.

FIG. 3A is a schematic elevational cross-sectional view for describing Lamb waves propagating through a piezoelectric film of an acoustic wave device of the related art, and FIG. 3B is a schematic elevational cross-sectional view for describing primary thickness-shear mode bulk waves propagating through a piezoelectric layer of an acoustic wave device according to a preferred embodiment of the present invention.

FIG. 4 is a diagram illustrating the amplitude direction of primary thickness-shear mode bulk waves.

FIG. 5A is a diagram illustrating the relationship between d/p and fractional bandwidth in use as a resonator, where p represents the center-to-center distance between adjacent electrodes, and d represents the thickness of a piezoelectric layer, and FIG. 5B is an enlarged view of a portion in FIG. 5A.

FIG. 6 is a diagram which illustrates the relationship between the amount of change of frequency per 1-nm change in the thickness of an additional film and t/p×100(%), and which illustrates a tendency in the amount of change of the frequency of a SAW device.

FIG. 7 is a diagram illustrating the relationship between t/p×100(%), at which the amount of change of frequency per 1-nm change in the thickness of an additional film is minimum, and the thickness of the additional film.

FIG. 8 is a diagram illustrating a reference example, in which spurious components appear, of resonance characteristics of an acoustic wave device.

FIG. 9 is a diagram illustrating the relationship between fractional bandwidth and the amount of phase rotation, which is used as the magnitude of spurious components and which is normalized by using 180 degrees, of the impedance of spurious components.

FIG. 10 is a diagram illustrating the relationship between d/p and metallization ratio MR.

FIG. 11 is an elevational cross-sectional view of an acoustic wave device according to a first modified example of a first preferred embodiment of the present invention.

FIG. 12 is a plan view of an acoustic wave device according to a second modified example of the first preferred embodiment of the present invention.

FIG. 13 is an elevational cross-sectional view of an acoustic wave device according to a third modified example of the first preferred embodiment of the present invention.

FIG. 14 is an elevational cross-sectional view of an acoustic wave device according to a fourth modified example of the first preferred embodiment of the present invention.

FIG. 15 is an elevational cross-sectional view of an acoustic wave device according to a fifth modified example of the first preferred embodiment of the present invention.

FIG. 16 is an elevational cross-sectional view of an acoustic wave device according to a sixth modified example of the first preferred embodiment of the present invention.

FIG. 17 is an elevational cross-sectional view of an acoustic wave device according to a seventh modified example of the first preferred embodiment of the present invention.

FIG. 18 is an elevational cross-sectional view of an acoustic wave device according to an eighth modified example of the first preferred embodiment of the present invention.

FIG. 19 is an elevational cross-sectional view of an acoustic wave device according to a ninth modified example of the first preferred embodiment of the present invention.

FIG. 20 is an elevational cross-sectional view of an acoustic wave device according to a tenth modified example of the first preferred embodiment of the present invention.

FIG. 21 is an elevational cross-sectional view of an acoustic wave device according to a second preferred embodiment of the present invention.

FIG. 22 is an elevational cross-sectional view of an acoustic wave device according to a first modified example of the second preferred embodiment of the present invention.

FIG. 23 is an elevational cross-sectional view of an acoustic wave device according to a second modified example of the second preferred embodiment of the present invention.

FIG. 24 is an elevational cross-sectional view of an acoustic wave device according to a third modified example of the second preferred embodiment of the present invention.

FIG. 25 is an elevational cross-sectional view of an acoustic wave device according to a third preferred embodiment of the present invention.

FIGS. 26A to 26D are elevational cross-sectional views, each of which is used to describe a piezoelectric layer and a pair of electrodes, of acoustic wave devices according to a fourth preferred embodiment of the present invention and its first to third modified examples.

FIG. 27 is a circuit diagram of a filter device according to a fifth preferred embodiment of the present invention.

### DETAILED DESCRIPTION OF THE PREFERRED EMBODIMENTS

Referring to the drawings, specific preferred embodiments of the present invention will be described below to clarify the present invention.

The preferred embodiments described in the specification are exemplary. It is to be noted that partial replacement or combination of configurations in different preferred embodiments may be made.

Each of first and second preferred embodiments of the present invention include a piezoelectric layer that is made of lithium niobate or lithium tantalate, a first electrode and a second electrode, and an additional film. The first electrode and the second electrode are disposed so as to face each other in the direction intersecting the thickness direction of the piezoelectric layer. The additional film is disposed on the piezoelectric layer or on at least one of the first electrode or the second electrode so as to overlap, in plan view, at least one of the following areas: areas in which the first electrode and the second electrode are located, and the area between the first electrode and the second electrode.

The first preferred embodiment of the present invention uses primary thickness-shear mode bulk waves. In the second preferred embodiment of the present invention, the first electrode is adjacent to the second electrode, and d/p is to be equal to or less than about 0.5 where d represents the thickness of the piezoelectric layer, and p represents the center-to-center distance between the first electrode and the second electrode. Thus, even when the size is reduced, the first and second preferred embodiments of the present invention enable the Q value to be improved. In addition, the frequency may be adjusted easily through the additional film which is disposed. Also in the filter device according to the third preferred embodiment of the present invention which includes the acoustic wave device according to the first and second preferred embodiments of the present invention, even when the size is reduced, the Q value may be improved, and the frequency may be adjusted easily.

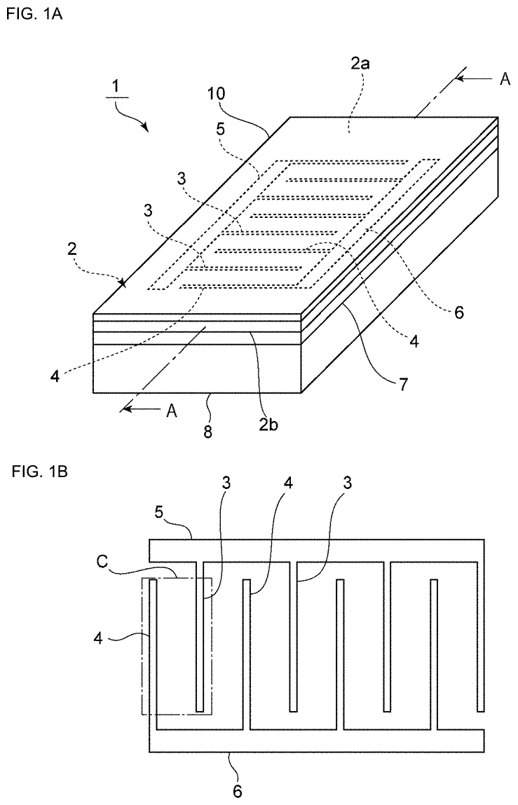

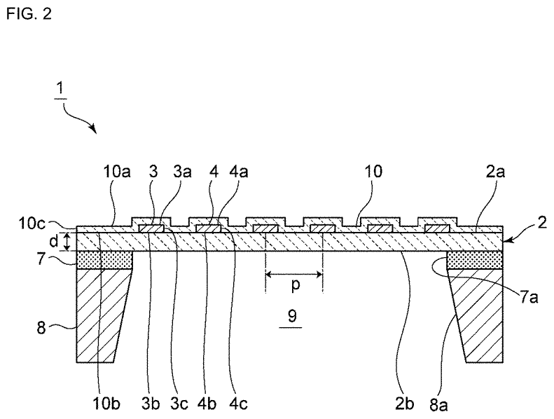

FIG. 1A is a schematic perspective view of the appearance of an acoustic wave device according to a first preferred embodiment of the first and second inventions. FIG. 1B is a plan view of the electrode structure on a piezoelectric layer. FIG. 2 is a cross-sectional view of a part along A-A line in FIG. 1A. In FIG. 1B, an additional film described below is not illustrated.

An acoustic wave device 1 includes a piezoelectric layer 2 made of lithium niobate. In the present preferred embodiment, the piezoelectric layer 2 is made of LiNbO₃. The piezoelectric layer 2 may be made of lithium tantalate (for example, LiTaO₃). The piezoelectric layer 2 includes first and second principal surfaces 2a and 2b which face each other. The thickness of the piezoelectric layer 2 is preferably equal to or greater than about 40 nm and equal to or less than about 1000 nm.

At least a pair of an electrode 3 and an electrode 4 is disposed on the first principal surface 2a. The electrode 3 is an exemplary “first electrode”, and the electrode 4 is an exemplary “second electrode”. In FIGS. 1A and 1B, multiple electrodes 3 are connected to a first busbar 5. Multiple electrodes 4 are connected to a second busbar 6. In the present preferred embodiment, the multiple electrodes 3 are connected to a first potential through the first busbar 5. The multiple electrodes 4 are connected to a second potential through the second busbar 6. The electrodes 3 and the electrodes 4 are interdigitated with each other. The electrodes 3 and the electrodes 4 each have a rectangular shape, and have a lengthwise direction. The electrodes 3 face their adjacent electrodes 4 in the direction orthogonal to the lengthwise direction. Both the lengthwise direction of the electrodes 3 and 4 and the direction orthogonal to the lengthwise direction of the electrodes 3 and 4 intersect with the thickness direction of the piezoelectric layer 2. Thus, the electrodes 3 may face their adjacent electrodes 4 in the direction intersecting with the thickness direction of the piezoelectric layer 2. Alternatively, the lengthwise direction of the electrodes 3 and 4 may be replaced with the direction orthogonal to the lengthwise direction of the electrodes 3 and 4 in FIGS. 1A and 1B. That is, in FIGS. 1A and 1B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 1A and 1B. Multiple configuration pairs, in each of which an electrode 3 connected to the first potential is adjacent to an electrode 4 connected to the second potential, are disposed in the direction orthogonal to the lengthwise direction of the electrodes 3 and 4. The number of pairs is not necessarily an integer, and may be, for example, 1.5 or 2.5. The state in which an electrode 3 is adjacent to an electrode 4 does not refer to the case in which the electrodes 3 and 4 are disposed so as to be in contact with each other directly, but refers to the case in which the electrode 3 and the electrode are disposed with a space interposed therebetween. When an electrode 3 is adjacent to an electrode 4, no electrodes, including the other electrodes 3 and 4, which are connected to a hot electrode and a ground electrode are disposed between the electrode 3 and the electrode 4.

In the present preferred embodiment, the electrodes 3 and 4 are rectangular in plan view. In some cases, the electrodes and 4 are not rectangular. In this case, the lengthwise direction may be set to the direction along a long side of a circumscribed polygon around an electrode 3 or 4 in plan view of the electrodes 3 and 4. When the electrodes 3 and the electrodes 4 connect with the first busbar 5 and the second busbar 6, “a circumscribed polygon around an electrode 3 or 4” encompasses a polygon circumscribing, at least, points of the electrode 3 or the electrode 4, other than points where the electrodes 3 and the electrodes 4 connect with the first busbar 5 and the second busbar 6.

As illustrated in FIG. 2, each electrode 3 includes a first surface 3a, a second surface 3b, and side surfaces 3c. The first surface 3a faces the second surface 3b in the thickness direction of the electrode 3. Among the first surface 3a and the second surface 3b, the second surface 3b is a surface positioned on the piezoelectric layer 2 side. The side surfaces 3c connect with the first surface 3a and the second surface 3b. Similarly, each electrode 4 includes a first surface 4a, a second surface 4b, and side surfaces 4c.

The center-to-center distance between adjacent electrodes 3 and 4 is preferably equal to or greater than about 1 μm and equal to or less than about 10 μm. The width of each of the electrodes 3 and the electrodes 4 is preferably equal to or greater than about 50 nm and equal to or less than about 1000 nm. The center-to-center distance between an electrode 3 and an electrode 4 refers to the distance between the center of the dimension (width dimension) of the electrode 3 in the direction orthogonal to the lengthwise direction of the electrode 3, and the center of the dimension (width dimension) of the electrode 4 in the direction orthogonal to the lengthwise direction of the electrode 4. When the electrodes 3 and 4 are not rectangular, the center-to-center distance between an electrode 3 and an electrode 4 may refer to the distance between the center of a dimension of the circumscribed polygon around the electrode 3 in the direction orthogonal to the lengthwise direction of the circumscribed polygon, and the center of a dimension of the circumscribed polygon around the electrode 4 in the direction orthogonal to the lengthwise direction of the circumscribed polygon.

In the present preferred embodiment, an additional film is disposed on the first principal surface 2a of the piezoelectric layer 2 so as to cover the electrodes 3 and 4. Any structure may be used as long as the additional film 10 is disposed on either one or both of the electrodes 3 and the electrodes 4, or on the piezoelectric layer 2, so as to overlap, in plan view, at least one of the following areas: areas in which the electrodes 3 and 4 are located, and areas between the electrodes 3 and the electrodes 4. In the acoustic wave device 1, the additional film covers the entire first principal surface 2a of the piezoelectric layer 2. The additional film 10 is made of silicon oxide. This enables the absolute value of the temperature coefficient of frequency TCF to be made small, and enables the frequency temperature characteristics to be improved. The material of the additional film 10 is not limited to the material described above, and an appropriate insulating material, such as, for example, silicon nitride, silicon oxynitride, alumina, or tantalum oxide, may be used. More preferably, the additional film 10 is a dielectric film, of which the lateral acoustic impedance is equal to or more than about 8.7M Rayl, such as the dielectric films show below in the Table.

The additional film 10 includes a first surface 10a, a second surface 10b, and end surfaces 10c. The first surface 10a faces the second surface 10b in the thickness direction of the additional film 10. Among the first surface 10a and the second surface 10b, the second surface 10b is a surface positioned on the piezoelectric layer 2 side. The end surfaces 10c connect with the first surface 10a and the second surface 10b.

The electrodes 3 and the electrodes 4, which are disposed on the piezoelectric layer 2, define a recess-protrusion structure. Therefore, in the present preferred embodiment, the first surface 10a and the second surface 10b of the additional film 10 each include recesses and protrusions in accordance with the recess-protrusion structure. Alternatively, the first surface 10a or the second surface 10b does not necessarily include recesses and protrusions, and may be flat.

In the specification, it is assumed that the thickness of a portion, which is disposed directly on the piezoelectric layer 2, of the additional film 10 is the distance between the piezoelectric-layer-side surface, which is in contact with the piezoelectric layer 2, of the additional film 10 and the surface which faces the piezoelectric-layer-side surface; the thickness of a portion, which is disposed on the electrodes 3, of the additional film 10 is the distance between the electrode-3-side surface, which is in contact with the electrodes 3, of the additional film 10 and the surface which faces the electrode-3-side surface; the thickness of a portion, which is disposed on the electrodes 4, of the additional film 10 is the distance between the electrode-4-side surface, which is in contact with the electrodes 4, of the additional film 10 and the surface which faces the electrode-4-side surface. In the present preferred embodiment, the thickness of the additional film 10 is the same in any of the portions. Alternatively, the thicknesses in the portions of the additional film 10 may be different from each other.

A supporting member 8 is disposed on the second principal surface 2b side of the piezoelectric layer 2 with an insulating layer 7 interposed in between. The insulating layer 7 and the supporting member 8 are each shaped as a frame. As illustrated in FIG. 2, the insulating layer 7 and the supporting member 8 include cavities 7a and 8a, respectively, which define an air gap 9. The air gap 9 is provided in order not to prevent vibrations in the excitation region of the piezoelectric layer 2. That is, the air gap 9 is located, in plan view, in an area, which overlaps at least a portion of a portion in which at least one pair of electrodes 3 and 4 is located, on the opposite side from the side on which the at least one pair of electrodes 3 and 4 is located. Therefore, the supporting member 8 is laminated on the second principal surface 2b with the insulating layer 7 interposed in between, at a position at which the supporting member 8 does not overlap the portion in which the at least one pair of electrodes 3 and 4 is disposed. The insulating layer 7 is not necessarily provided. Therefore, the supporting member 8 may be laminated directly or indirectly on the second principal surface 2b of the piezoelectric layer 2. In plan view, the supporting member 8 may be disposed, not only at a position at which the supporting member 8 does not overlap the portion in which the at least one pair of electrodes 3 and 4 is disposed, but also at a position at which the supporting member 8 overlaps the portion in which the at least one pair of electrodes 3 and 4 is disposed. In this case, the air gap 9 is provided between the piezoelectric layer 2 and the supporting member 8, at a position at which the supporting member 8 overlaps, in plan view, the portion in which the at least one pair of electrodes 3 and 4 is disposed.

The insulating layer 7 is made of silicon oxide. Other than silicon oxide, an appropriate insulating material, such as silicon oxynitride or alumina, may be used. The supporting member 8 is made of Si. When the supporting member 8 is made of Si, the surface orientation of the surface on the piezoelectric layer 2 side is preferably (100), (110), or (111). The resistivity of the Si substrate is preferably equal to or greater than about 4 kΩ. The supporting member 8 may be made also of an appropriate insulating material or semiconductor material.

The multiple electrodes 3, the multiple electrodes 4, and the first and second busbars 5 and 6 are made of an appropriate metal or alloy, such as Al or AlCu alloy. Cu in AlCu alloy is preferably equal to or greater than about 1% by weight and equal to or less than about 20% by weight. The multiple electrodes 3, the multiple electrodes 4, and the first and second busbars 5 and 6 may be made of a laminated metal film obtained by laminating multiple metal layers. In this case, for example, a close-contact layer may be included. Examples of a close-contact layer include a Ti layer and a Cr layer.

In driving, an alternating voltage is applied between the electrodes 3 and the electrodes 4. More specifically, an alternating voltage is applied between the first busbar 5 and the second busbar 6. This enables acquisition of resonance characteristics obtained by using primary thickness-shear mode bulk waves excited in the piezoelectric layer 2. In the acoustic wave device 1, when d represents the thickness of the piezoelectric layer 2 and p represents the center-to-center distance between any adjacent electrodes 3 and 4 among multiple pairs of electrodes 3 and 4, d/p is to be equal to or less than about 0.5. Therefore, the primary thickness-shear mode bulk waves are excited effectively, and good resonance characteristics may be obtained. More preferably, d/p is preferably equal to or less than about 0.24. In this case, much better resonance characteristics may be obtained. As in the present preferred embodiment, when either one or both of the electrodes 3 and the electrodes 4 are more than one, that is, when the number of pairs of electrodes 3 and 4 is 1.5 or more where an electrode 3 and an electrode 4 are regarded as one pair of electrodes, the center-to-center distance p between adjacent electrodes 3 and 4 refers to the center-to-center distance of each pair of adjacent electrodes 3 and 4.

In the present preferred embodiment, since the piezoelectric layer 2 is made of a Z-cut piezoelectric material, the direction orthogonal to the lengthwise direction of the electrodes 3 and 4 is the direction orthogonal to the polarization direction of the piezoelectric layer 2. This does not apply to the case in which another cut-angle piezoelectric material is used for the piezoelectric layer 2. The term, “orthogonal”, is not limited only to the case of being strictly orthogonal, and may refer to the case of being substantially orthogonal (the case in which the angle of the lengthwise direction of the electrodes 3 and 4 with respect to the polarization direction of the piezoelectric layer 2 is, for example, an angle within a range of about 90°±10°).

Since the acoustic wave device 1 according to the present preferred embodiment has the configuration described above, a reduction of the Q value is difficult to occur even when the number of pairs of electrodes 3 and 4 is decreased for a reduction in size. In addition, the frequency may be adjusted easily. In the description below, the effect that a reduction of the Q value is difficult to occur will be described. Then, the effect of easy adjustment of the frequency will be described.

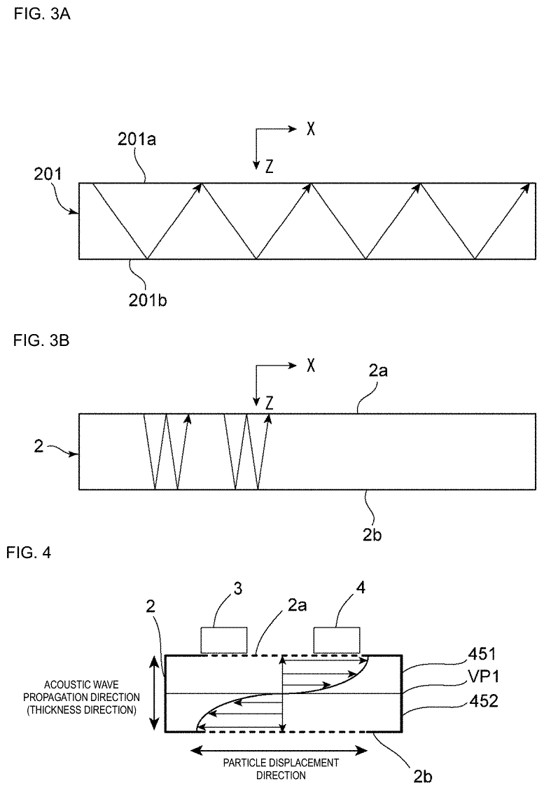

The size may be reduced, for example, by decreasing the number of electrode fingers in reflectors disposed on both sides of an area in which the electrodes 3 and 4 are disposed. According to the present preferred embodiment, even when the number of electrode fingers of the reflectors is decreased for a reduction in size, the energy is confined in and near the excitation region. Thus, a reduction in size leads to just a small amount of propagation loss, and a reduction of the Q value is difficult to occur. In addition, just a small amount of propagation loss, as described above, results from use of primary thickness-shear mode bulk waves. The difference between Lamb waves used by an acoustic wave device of the related art and the primary thickness-shear mode bulk waves will be described by referring to FIGS. 3A and 3B.

FIG. 3A is a schematic elevational cross-sectional view for describing Lamb waves propagating through a piezoelectric film of the acoustic wave device as described in Japanese Unexamined Patent Application Publication No. 2012-257019. In FIG. 3A, waves propagate in a piezoelectric film 201 as illustrated by using arrows. In the piezoelectric film 201, a first principal surface 201a faces a second principal surface 201b. The thickness direction connecting the first principal surface 201a and the second principal surface 201b is Z direction. X direction is a direction in which the electrode fingers of an IDT electrode are arranged. As illustrated in FIG. 3A, Lamb waves propagate in X direction. Since Lamb waves are plate waves, the entire piezoelectric film 201 vibrates. However, since the waves propagate in X direction, reflectors are disposed on both the sides to obtain resonance characteristics. Therefore, when the size is reduced, that is, the number of pairs of electrode fingers is decreased, propagation loss of the waves occurs, resulting in a reduction of the Q value.

In contrast, as illustrated in FIG. 3B, in the acoustic wave device according to the present preferred embodiment, the vibration displacement occurs in the thickness-shear direction. Thus, waves propagate, for resonance, almost in the direction connecting the first principal surface 2a and the second principal surface 2b of the piezoelectric layer 2, that is, in Z direction. That is, X direction components of waves are much less than Z direction components. The propagation of waves in Z direction causes resonance characteristics to be obtained. Thus, even when the number of electrode fingers of the reflectors is decreased, propagation loss is difficult to occur. Further, even if the number of pairs of electrodes including an electrode 3 and an electrode 4 is decreased for a reduction in size, a reduction of the Q value is difficult to occur.

As illustrated in FIG. 4, the amplitude direction of the primary thickness-shear mode bulk waves in a first region 451 included in the excitation region of the piezoelectric layer 2 is opposite to that in a second region 452 included in the excitation region. FIG. 4 schematically illustrates bulk waves produced when voltages are applied between the electrodes 3 and the electrodes 4 so that the voltage applied to the electrodes 4 is higher than that to the electrodes 3. The first region 451 is a region that is included in the excitation region and that is positioned between the first principal surface 2a and a virtual plane VP1 which is orthogonal to the thickness direction of the piezoelectric layer 2 and with which the piezoelectric layer 2 is divided into two. The second region 452 is a region that is included in the excitation region and that is positioned between the virtual plane VP1 and the second principal surface 2b.

As described above, in the acoustic wave device 1, at least one pair of electrodes including an electrode 3 and an electrode 4 is disposed. Since waves do not propagate in X direction, the number of pairs of electrodes including an electrode 3 and an electrode 4 is not necessarily more than one. That is, any structure may be used as long as at least one pair of electrodes is disposed.

For example, the electrodes 3 are connected to the hot potential, and the electrodes 4 are connected to the ground potential. Alternatively, the electrodes 3 may be connected to the ground potential, and the electrodes 4 may be connected to the hot potential. In the present preferred embodiment, as described above, at least one pair of electrodes has an electrode connected to the hot potential and an electrode connected to the ground potential, and a floating electrode is not provided.

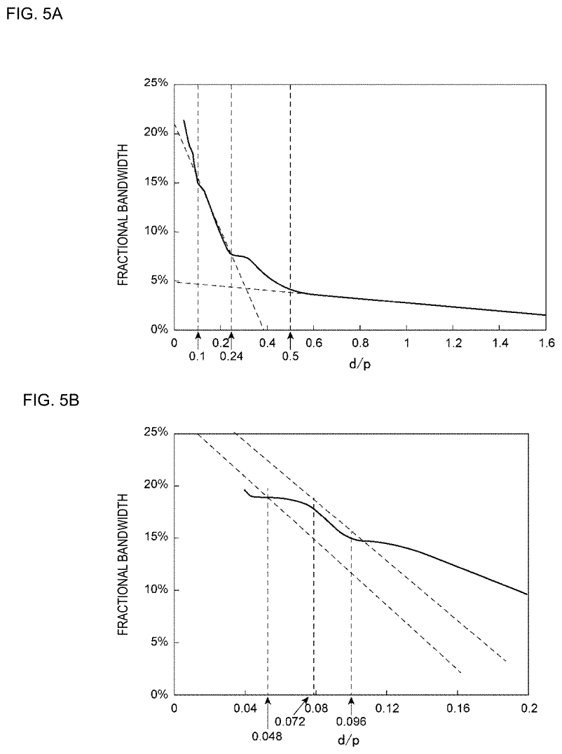

When d represents the thickness of the piezoelectric layer 2 and p represents the electrode center-to-center distance between an electrode 3 and an electrode 4, as described above, in the present preferred embodiment, d/p is equal to or less than about 0.5, and is more preferably equal to or less than about 0.24. This will be described by referring to FIGS. 5A and 5B.

Multiple acoustic wave devices were obtained by changing d/p. FIG. 5A is a diagram illustrating the relationship between d/p and fractional bandwidth obtained by using the acoustic wave devices as resonators.

As is clear from FIG. 5A, when d/p>about 0.5, even if d/p is adjusted, the fractional bandwidth is less than about 5%. In contrast, when d/p about 0.5, if d/p is varied in that range, the fractional bandwidth of about 5% or more may be obtained. That is, a resonator having a high coupling coefficient may be formed. When d/p is equal to or less than about 0.24, the fractional bandwidth may increase to about 7% or more. In addition, if d/p is adjusted in this range, a resonator having a much wider fractional bandwidth may be obtained, and a resonator having a much higher coupling coefficient is achieved. Therefore, like the second preferred embodiment of the present invention, it is discovered that, by setting d/p to about 0.5 or less, a resonator, which uses the primary thickness-shear mode bulk waves and which has a high coupling coefficient, may be provided.

In addition, as is clear from FIG. 5A, when d/p≤0.10, if d/p is varied in the range of 0<d/p≤0.10, the coupling coefficient may be further improved, and the fractional bandwidth may further increase.

FIG. 5B is a graph obtained by enlarging a portion in FIG. 5A. As illustrated in FIG. 5B, when d/p≤0.096, if d/p is varied in the range of d/p≤0.096, the coupling coefficient may be further improved, and the fractional bandwidth may further increase. If 0.048≤d/p≤0.072, the coupling coefficient may be much further improved, and the fractional bandwidth may much further increase.

As described above, at least one pair of electrodes may be one pair, and p described above is set to the center-to-center distance between the adjacent electrodes 3 and 4 in the case of one pair of electrodes. In the case of 1.5 or more pairs of electrodes, p may be set to the center-to-center distance between adjacent electrodes 3 and 4.

As described above, in the present preferred embodiment, the additional film 10 is disposed on the first principal surface 2a of the piezoelectric layer 2 so as to cover the electrodes 3 and 4. This enables easy adjustment of the frequency. This will be described below.

Multiple acoustic wave devices, having the configuration according to the first preferred embodiment and having different thicknesses of the additional film 10 and different electrode center-to-center distances, were prepared. The thickness of the additional film 10 is represented by t, and the ratio of the thickness t with respect to the electrode center-to-center distance p is represented by t/p×100(%). The design parameters of the acoustic wave devices are as follows.

The piezoelectric layer 2: LiNbO₃, a thickness of 400 nm

The number of pairs of electrodes including an electrode 3 and an electrode 4=50 pairs

The additional film 10: a silicon oxide film whose thickness is 10 nm or 20 nm

The insulating layer 7: a silicon oxide film whose thickness is 0.3 μm

The supporting member 8: Si

The length of the excitation region=20 μm

The electrode center-to-center distance: varied in a range from 2 μm to 20 μm

The width of each of the electrodes 3 and 4=0.5 μm

d/p: varied in a range from 0.05 to 0.5

t/p×100(%): varied in a range from 0.1% to 2%

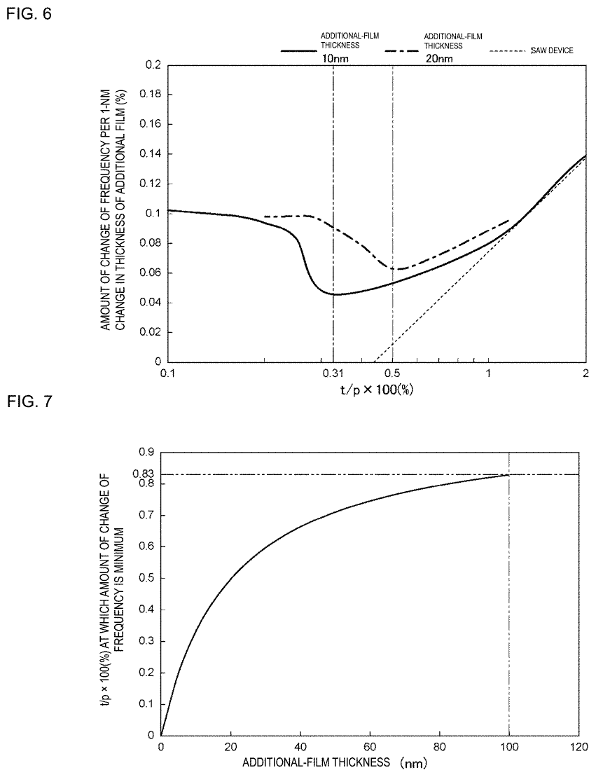

In the multiple acoustic wave devices, the amount of change of the frequency, which is obtained when the thickness of the additional film 10 is varied by about 1 nm, was measured. FIG. 6 illustrates the result. FIG. 6 also illustrates, in addition to the result described above, the tendency of the amount of change of the frequency in an acoustic wave device, which is a SAW device, as described in Japanese Unexamined Patent Application Publication No. 2012-257019.

FIG. 6 is a diagram illustrating the relationship between the amount of change of the frequency per 1-nm change in the thickness of the additional film and t/p×100(%), and also illustrating the tendency of the amount of change of the frequency of the SAW device. When the thickness t of the additional film 10 is about 10 nm, t/p×100(%) is changed by varying the electrode center-to-center distance p while the thickness t is constant. The same is true for the case in which the thickness t of the additional film 10 is about 20 nm.

As is clear from FIG. 6, in the SAW device, the less t/p×100(%) is, the smaller the amount of change of the frequency is.

In contrast, in the case of having the configuration according to the present preferred embodiment and having the additional film 10 whose thickness t is 10 nm, when t/p×100(%) is about 0.31%, the minimum is obtained. In other words, when the thickness t of the additional film 10 is about 10 nm and the electrode center-to-center distance p is about 3 μm, the amount of change of the frequency per 1-nm change in the thickness of the additional film is minimum. More specifically, when t/p×100(%) is greater than about 0.31%, as t/p×100(%) is less, the amount of change of the frequency is smaller. In the case where the thickness t of the additional film 10 is about 20 nm, when t/p×100(%) is about 0.5%, the minimum is obtained. In other words, when the thickness t of the additional film 10 is about 20 nm and the electrode center-to-center distance p is about 4 μm, the amount of change of the frequency per 1-nm change in the thickness of the additional film is minimum. More specifically, when t/p×100(%) is equal to or less than about 0.5%, as t/p×100(%) is less, the amount of change of the frequency is larger. Thus, in the present preferred embodiment, even when t/p×100(%) is less, the amount of change of the frequency is sufficiently large. Therefore, adjustment of the thickness of the additional film 10 enables the frequency to be adjusted easily.

Also when the thickness t of the additional film 10 is neither about 10 nm nor about 20 nm, t/p×100(%), at which the amount of change of the frequency per 1-nm change in the thickness t of the additional film 10 is minimum, was determined. The thickness of the additional film was varied in a range of about 100 nm or less.

FIG. 7 is a diagram illustrating the relationship between t/p×100(%), at which the amount of change of the frequency per 1-nm change in the thickness of the additional film is minimum, and the thickness of the additional film.

As is clear from FIG. 7, in any case of the thickness t of the additional film 10, the amount of change of the frequency is reduced or minimized. Therefore, in any case of the thickness t of the additional film 10, as in the case illustrated in FIG. 6, even if t/p×100(%) is small, the amount of change of the frequency is not less than the minimum, and is sufficiently large. Therefore, adjustment of the thickness of the additional film 10 enables the frequency to be adjusted easily. As illustrated in FIG. 7, as the additional film 10 is thinner, t/p×100(%), at which the amount of change of the frequency is minimum, is less.

The thickness t of the additional film 10 is preferably equal to or less than the thickness of each of the electrodes 3 and the electrodes 4. If the additional film 10 is too thick, when the acoustic wave device 1 is used in a filter device such as a band pass filter, the insertion loss may degrade.

The thickness t of the additional film 10 is more preferably equal to or less than about 100 nm. This may reduce or prevent degradation of the insertion loss effectively when the acoustic wave device 1 according to the present preferred embodiment is used in a filter device such as a band pass filter.

As illustrated in FIG. 7, the thickness t of the additional film 10 is 100 nm, t/p×100(%), at which the amount of change of the frequency is minimum, is about 0.83%. As described above, as the additional film 10 is thinner, t/p×100(%), at which the amount of change of the frequency is minimum, is less. Therefore, t/p×100(%) is preferably equal to or less than about 0.83%. In this case, when the acoustic wave device 1 according to the present preferred embodiment is used in a filter device such as a band pass filter, degradation of the insertion loss may be suppressed effectively.

The lower limit of the thickness of the additional film 10 is not particularly limited, but, for example, is preferably about 1 nm. In this case, the additional film 10 may be formed easily.

The lower limit of t/p×100(%) is not particularly limited, but is preferably about 0.01(%).

The influence on the frequency, which is exerted by the additional film 10, is particularly large in a portion of the additional film 10, which is positioned in the areas between the electrodes 3 and the electrodes 4. In the present preferred embodiment, the additional film 10 is disposed on the electrodes 3 and the electrodes 4 and on the piezoelectric layer 2 so as to overlap, in plan view, the entirety of both the areas, in which the electrodes 3 and 4 are formed, and the areas between the electrodes 3 and the electrodes 4. Therefore, the frequency may be adjusted much more easily. In the present preferred embodiment, since the additional film 10 covers the electrodes 3 and the electrodes 4, the electrodes 3 and the electrodes 4 are difficult to damage.

In the acoustic wave device 1, the additional film 10 is also disposed in a peripheral area between the peripheral line of the first principal surface 2a of the piezoelectric layer 2 and the area in which the electrodes 3 and the electrodes 4 are formed. However, the additional film 10 is not necessarily provided in the peripheral area.

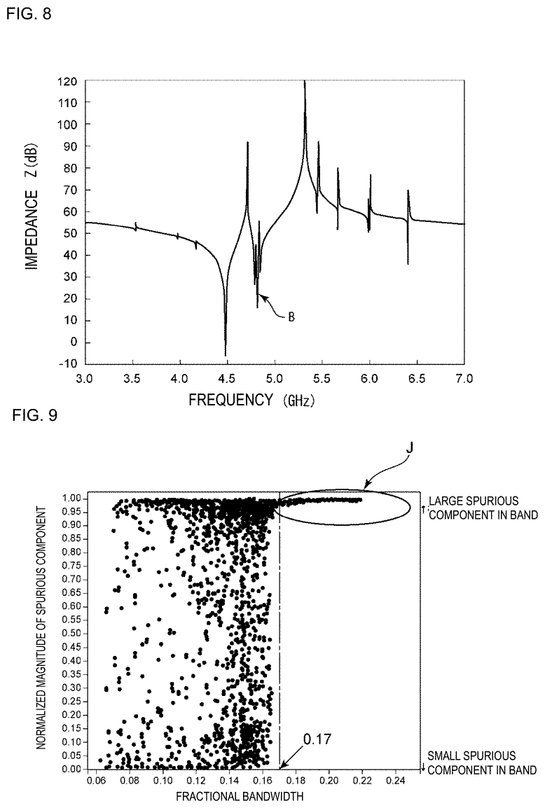

In the acoustic wave device 1, when viewed in the direction in which, among multiple pairs of an electrode 3 and an electrode 4, any adjacent electrodes 3 and 4 face each other, an excitation zone corresponds to an overlapping area in which the adjacent electrodes 3 and 4 overlap each other. A metallization ratio MR of the adjacent electrodes 3 and 4 with respect to the excitation zone preferably satisfies an expression, MR≤1.75(d/p)+0.075. In this case, spurious components may be reduced effectively. This will be described by referring to FIGS. 8 and 9. FIG. 8 is a reference diagram illustrating exemplary resonance characteristics of the acoustic wave device 1. Spurious components illustrated by using arrow B appear between the resonant frequency and the anti-resonant frequency. It is assumed that d/p=about 0.08 and Euler angles of LiNbO₃ are (0°, 0°, 90°). It is assumed that the metallization ratio MR=about 0.35.

The metallization ratio MR will be described by referring to FIG. 1B. In the electrode structure in FIG. 1B, when a pair of an electrode 3 and an electrode 4 is focused on, assume that only this single pair of an electrode 3 and an electrode 4 is provided. In this case, the portion surrounded by using a long dashed short dashed line is an excitation zone C. The excitation zone indicates the following areas obtained when the electrode 3 and the electrode 4 are viewed in the direction orthogonal to the lengthwise direction of the electrodes 3 and 4, that is, the direction in which the electrode 3 faces the electrode 4: an area of the electrode 3 in which the electrode 3 overlaps the electrode 4, an area of the electrode 4 in which the electrode 4 overlaps the electrode 3, and an area, in which the electrode 3 overlaps the electrode 4, in the area between the electrode 3 and the electrode 4. The metallization ratio MR is the area of the electrodes 3 and 4 in the excitation zone C with respect to the area of the excitation zone. That is, the metallization ratio MR is a ratio of the area of the metallization portion with respect to the area of the excitation zone.

When multiple pairs of electrodes are disposed, MR may be a ratio of the metallization portion, which is included in all the excitation zones, with respect to the total area of the excitation zones.

FIG. 9 is a diagram illustrating the relationship between fractional bandwidth and the amount of phase rotation, which is used as the magnitude of spurious components and which is normalized by using 180 degrees, of impedance of spurious components. The relationship is obtained when many acoustic wave resonators were provided according to the present preferred embodiment. To obtain fractional bandwidths, the film thickness of the piezoelectric layer and the dimension of electrodes are varied and adjusted. FIG. 9 illustrates the result obtained when a piezoelectric layer made of Z-cut LiNbO₃ is used. Also in the case where a piezoelectric layer having another cut-angle is used, a similar tendency is obtained. For example, a rotated Y-cut or X-cut piezoelectric layer may be used.

In the area surrounded by ellipse J in FIG. 9, the magnitude of spurious components is as much as about 1.0. As is clear from FIG. 9, when the fractional bandwidth exceeds about 0.17, that is, when the fractional bandwidth exceeds about 17%, large spurious components, whose spurious level is equal to or greater than one, appear in the pass band even if the parameters for forming the fractional bandwidth are varied. That is, like the resonance characteristics illustrated in FIG. 8, large spurious components illustrated by using arrow B appear in the band. Therefore, the fractional bandwidth is preferably equal to or less than about 17%. In this case, spurious components may be reduced by adjusting, for example, the film thickness of the piezoelectric layer 2 and the dimension of the electrodes 3 and 4.

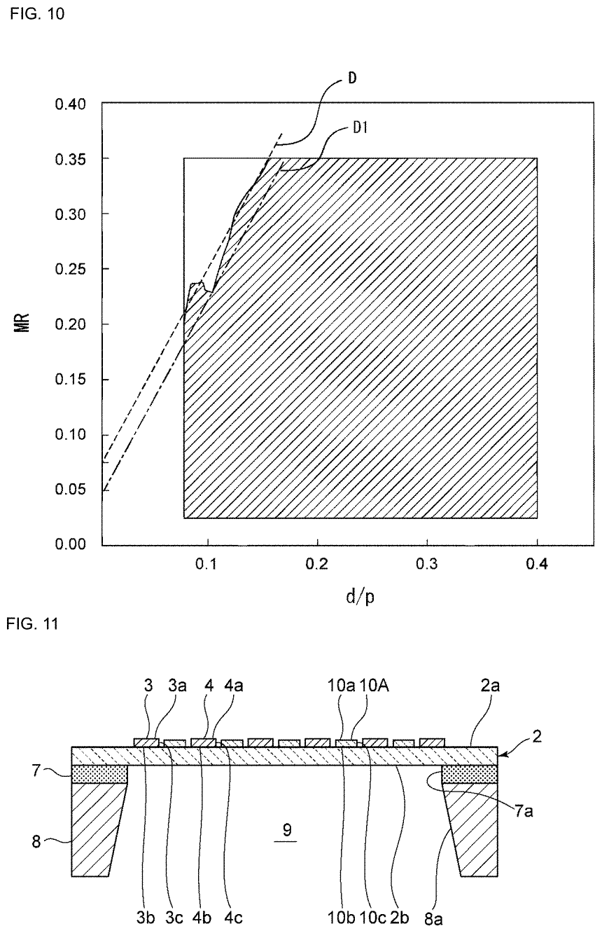

FIG. 10 is a diagram illustrating the relationship between d/p, metallization ratio MR, and fractional bandwidth. By using the acoustic wave device described above, various acoustic wave devices having different values of d/p and MR were formed, and their fractional bandwidths were measured. The hatched portion to the right from dashed line D in FIG. 10 indicates an area in which the fractional bandwidth is equal to or less than about 17%. The boundary between the area with hatches and the area without hatches is expressed in an expression, MR=1.75(d/p)+0.075. Therefore, preferably, MR≤1.75(d/p)+0.075. In this case, the fractional bandwidth equal to or less than about 17% is obtained easily. More preferable area is the area to the right from the long dashed short dashed line D1, in FIG. 10, which is expressed in an expression, MR=1.75(d/p)+0.05. That is, if MR≤1.75(d/p)+0.05, the fractional bandwidth equal to or less than about 17% is surely obtained.

As described above, in the acoustic wave devices according to the first and second preferred embodiments of the present invention, even when the number of electrode fingers of the reflectors is reduced, good resonance characteristics may be obtained. Therefore, even when the size is reduced, a high Q value may be achieved. In addition, the frequency may be adjusted easily. Modified examples of the first preferred embodiment will be described below. The modified examples are different from the first preferred embodiment only in the portion in which the additional film 10 is disposed. The modified examples also may obtain an effect similar to that of the first preferred embodiment.

In a first modified example illustrated in FIG. 11, an additional film 10A is disposed only in the area between an electrode 3 and an electrode 4 on the first principal surface 2a of the piezoelectric layer 2. In other words, the additional film 10A is disposed so as to overlap, in plan view, the area between an electrode 3 and an electrode 4. More specifically, multiple additional films 10A are disposed in the respective areas between the electrodes 3 and the electrodes 4. A single additional film 10A, which is rectangular in plan view, is disposed in each area between the electrodes 3 and the electrodes 4. The shape of the additional film 10A is not limited to the shape described above. The end surfaces 10c of each additional film 10A are positioned in the corresponding area between an electrode 3 and an electrode 4. In the present modified example, both the first surface 10a and the second surface 10b of each additional film 10A do not have recesses and protrusions, and are flat. Each additional film 10A may reach the side surface 3c of the corresponding electrode 3 or the side surface 4c of the corresponding electrode 4. Thus, the expression, “an additional film overlaps, in plan view, the area between an electrode 3 and an electrode 4”, also encompasses the case in which the additional film overlaps, at least partially, the area between an electrode 3 and an electrode 4 in plan view.

As described above, the influence on the frequency, which is caused by the additional film, is particularly large in the portion, which is positioned in the area between an electrode 3 and an electrode 4, of the additional film. In the present modified example, the additional films 10A are disposed in areas between the electrodes 3 and the electrodes 4. Therefore, the frequency may be adjusted much more easily.

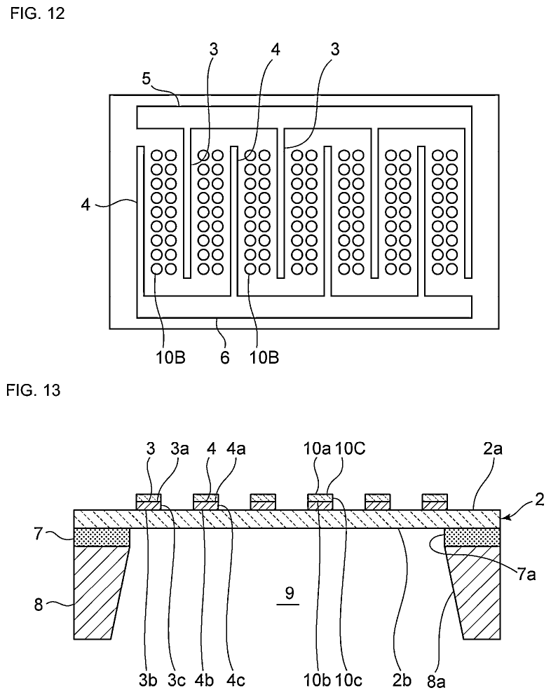

In a second modified example illustrated in FIG. 12, like the first modified example, an additional film 10B is disposed only in the area between an electrode 3 and an electrode 4 on the first principal surface 2a of the piezoelectric layer 2. In other words, the additional film 10B is disposed so as to overlap, in plan view, the area between an electrode 3 and an electrode 4. In the present modified example, multiple additional films 10B are disposed in each area between the electrodes 3 and the electrodes 4. Each additional film 10B is circular in plan view. Thus, multiple additional films 10B may be formed through patterning. In the present modified example, the pattern shape or the area of the multiple additional films 10B are adjusted appropriately. Thus, a desired frequency may be obtained easily. The patterning of the multiple additional films 10B may be performed in the areas, in which the electrodes 3 and the electrodes 4 are provided, and an area, in which the first busbar 5 or the second busbar 6 is provided.

The pattern shape of each additional film 10B in the present modified example is circular. This is not limited. For example, the pattern shape of each additional film 10B may be an ellipse or a rectangle. Alternatively, the pattern shape of each additional film 10B may be, for example, a shape, in which multiple circles overlap each other partially, or a shape, in which multiple rectangles overlap each other partially. The pattern of each additional films 10B may be a pattern in which the additional film 10B has at least one cavity, or a pattern, in which a portion of the additional film 10B is thin.

In a third modified example illustrated in FIG. 13, additional films 10C are disposed only on the first surfaces 3a of the electrodes 3 and the first surfaces 4a of the electrodes 4. In other words, in the present modified example, the additional films 10C are disposed so as to overlap, in plan view, the areas in which the electrodes 3 and the electrodes 4 are formed. The additional films 10C may reach the side surfaces 3c of the electrodes 3 or the side surfaces 4c of the electrodes 4.

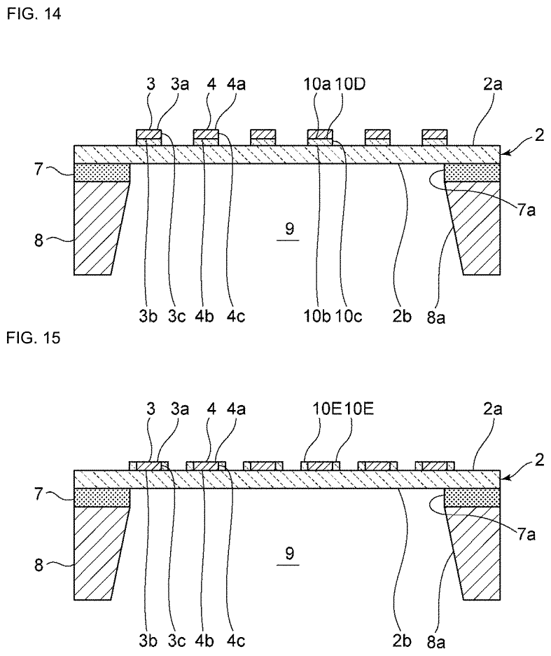

In a fourth modified example illustrated in FIG. 14, additional films 10D are disposed only between the electrodes 3 and 4 and the piezoelectric layer 2. In other words, in the present modified example, the additional films 10D are disposed so as to overlap, in plan view, the areas in which the electrodes 3 and the electrodes 4 are located. The additional films 10D may reach the areas between the electrodes 3 and the electrodes 4 on the first principal surface 2a of the piezoelectric layer 2.

In the present modified example, the additional films 10D are disposed between the electrodes 3 and 4 and the piezoelectric layer 2. Thus, the metal layer, of which the electrodes 3 and the electrodes 4 are formed, does not form a triaxial orientation.

In a fifth modified example illustrated in FIG. 15, additional films 10E are disposed on the side surfaces 3c of the electrodes 3, and are not disposed on the first surfaces 3a and the second surfaces 3b of the electrodes 3. Similarly, additional films 10E are disposed on the side surfaces 4c of the electrodes 4, and are not disposed on the first surfaces 4a and the second surfaces 4b of the electrodes 4. The additional films 10E reach the first principal surface 2a of the piezoelectric layer 2. In other words, the additional films 10E are disposed so as to overlap, in plan view, the areas between the electrodes 3 and the electrodes 4.

The case in which an additional film is disposed on an electrode 3 also encompasses the case in which, as in the present modified example, additional films 10E are provided only on the side surfaces 3c of the electrode 3. Similarly, the case in which an additional film is disposed on an electrode 4 also encompasses the case in which additional films 10E are provided only on the side surfaces 4c of the electrode 4.

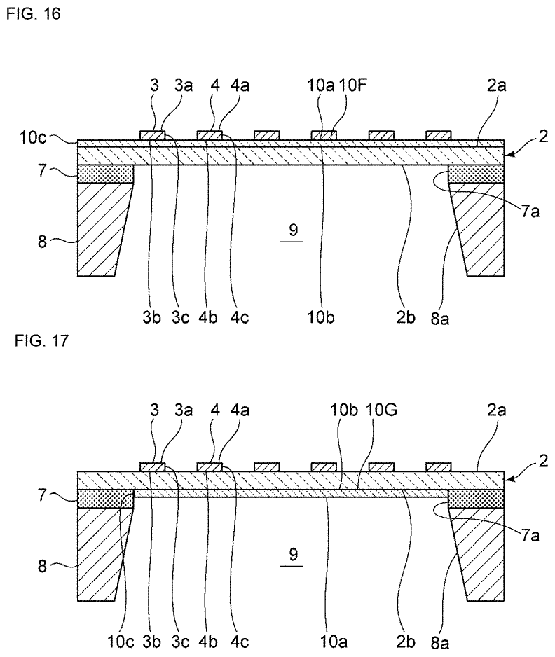

In a sixth modified example illustrated in FIG. 16, an additional film 10F is disposed on the first principal surface 2a of the piezoelectric layer 2. The electrodes 3 and the electrodes 4 are disposed on the additional film 10F. The additional film 10F is disposed on the first principal surface 2a of the piezoelectric layer 2 so as to overlap, in plan view, the entirety of both the areas, in which the electrodes 3 and 4 are located, and the areas between the electrodes 3 and the electrodes 4. The additional film 10F may cover the entire first principal surface 2a.

In a seventh modified example illustrated in FIG. 17, an additional film 10G is disposed on the second principal surface 2b of the piezoelectric layer 2 so as to overlap, in plan view, the entirety of both the areas, in which the electrodes 3 and 4 are located, and the areas between the electrodes 3 and the electrodes 4. The additional film 10G may be disposed on the second principal surface 2b so as to overlap, in plan view, at least one of the areas: the areas, in which the electrodes 3 and 4 are located, and the areas between the electrodes 3 and the electrodes 4. Alternatively, the additional film 10G may be disposed on both the first principal surface 2a and the second principal surface 2b so as to overlap, in plan view, at least one of the areas: the areas, in which the electrodes 3 and 4 are located, and the areas between the electrodes 3 and the electrodes 4.

Eighth to tenth modified examples, in which only the shape of the cross section of an additional film is different from that in the first preferred embodiment, will be described below. Also in the eighth to tenth modified examples, similarly to the first preferred embodiment, even when the size is reduced, the Q value may be improved, and the frequency may be adjusted easily.

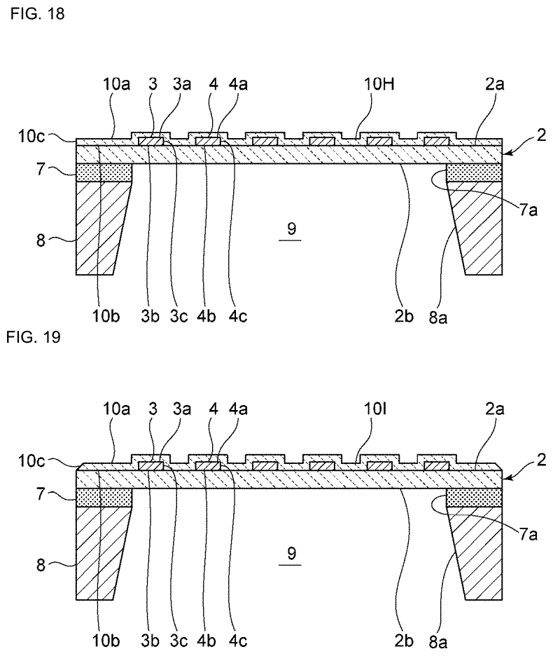

In an eighth modified example illustrated in FIG. 18, the thickness of a portion of an additional film 10H, which is disposed on the electrodes 3 and the electrodes 4, is thinner than the thickness of a portion of the additional film 10H, which is disposed on the piezoelectric layer 2. Since the additional film 10H is disposed on the electrodes 3 and the electrodes 4, the electrodes 3 and the electrodes 4 are difficult to damage. In addition, since the additional film 10H has such a thin portion, the amount of the additional film 10H may be reduced, and the productivity may be improved.

In a ninth modified example illustrated in FIG. 19, the end surfaces 10c of an additional film 10I extend at an inclination with respect to the direction in which the first surface 10a faces the second surface 10b. More specifically, in plan view, the peripheral line of the first surface 10a of the additional film 10I is positioned inside the peripheral line of the second surface 10b. When the end surfaces 10c extend at an inclination as described above, spurious components are easy to be scattered at the end surfaces 10c. The inclination angle of the end surfaces 10c with respect to the direction in which the first surface 10a faces the second surface 10b is not necessarily constant. In this case, for example, the end surfaces 10c may have stepped portions.

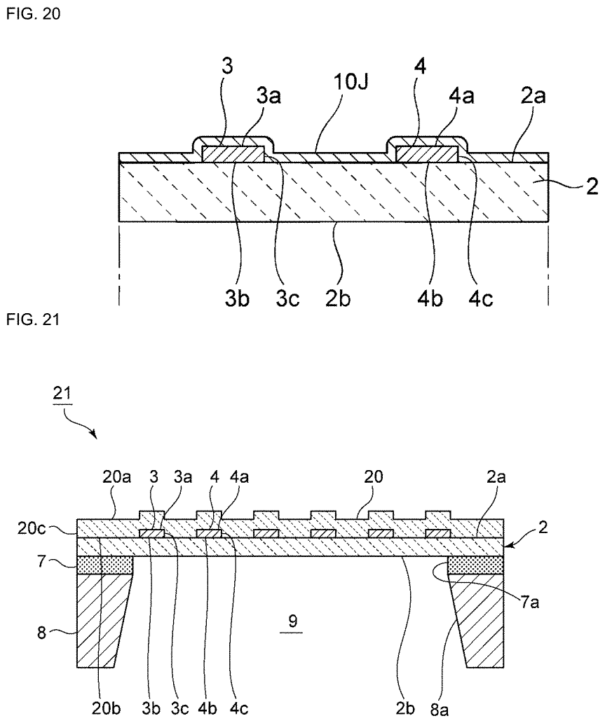

In a tenth modified example illustrated in FIG. 20, an additional film 10J has curved shapes in and near its portions which overlap, in plan view, the ridge lines between the first surfaces 3a and the side surfaces 3c of the electrodes 3. Similarly, the additional film 10J has curved shapes in and near its portions which overlap, in plan view, the ridge lines between the first surfaces 4a and the side surfaces 4c of the electrodes 4.

FIG. 21 is an elevational cross-sectional view of an acoustic wave device according to a second preferred embodiment. An acoustic wave device 21 is different from the first preferred embodiment in that an additional film 20 is thicker than each of the electrodes 3 and the electrodes 4. The electrodes 3 and the electrodes 4 are embedded under the additional film 20. Other than the point described above, the acoustic wave device 21 according to the second preferred embodiment has substantially the same configuration as that of the acoustic wave device 1 according to the first preferred embodiment.

Also in the second preferred embodiment, like the first preferred embodiment, even when the size is reduced, the Q value may be improved, and the frequency may be adjusted easily. Further, also in the modified examples of the second preferred embodiment which are described below, substantially the same effect may be obtained.

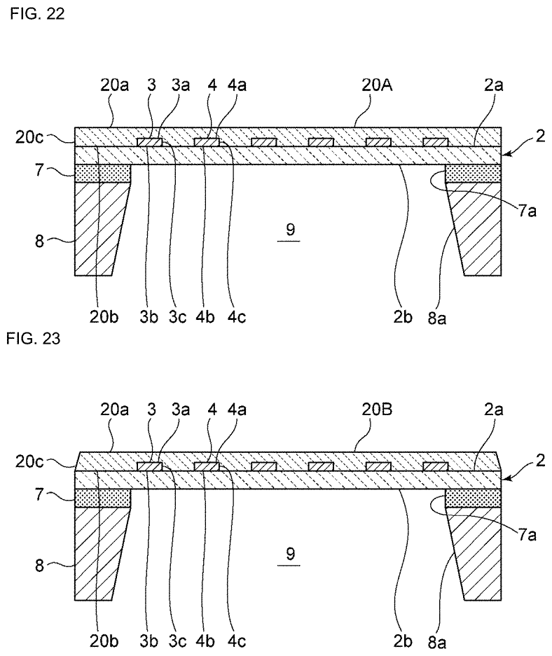

In a first modified example illustrated in FIG. 22, a first surface 20a of an additional film 20A does not have recesses and protrusions, and is flat.

Also in a second modified example illustrated in FIG. 23, the first surface 20a of an additional film 20B is flat. In addition, end surfaces 20c of the additional film 20B extend at an inclination with respect to the direction in which the first surface 20a faces a second surface 20b.

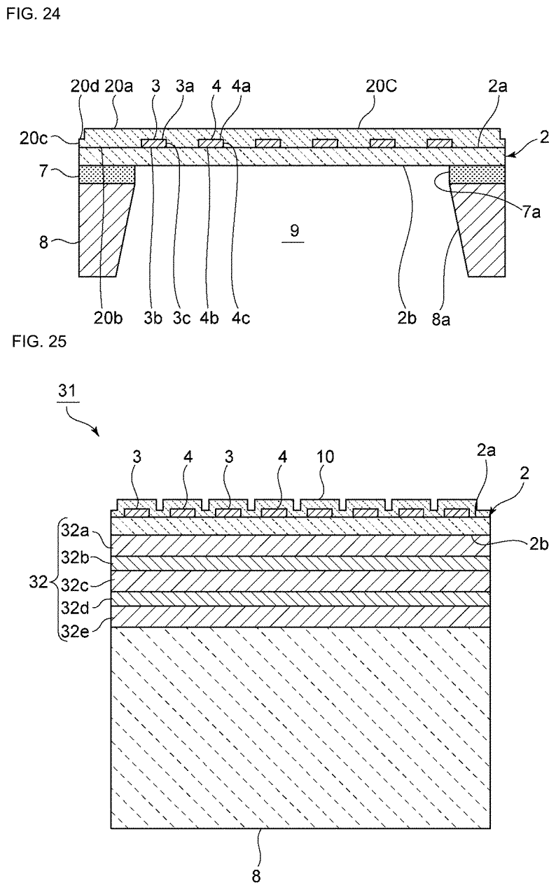

Also in a third modified example illustrated in FIG. 24, the first surface 20a of an additional film 20C is flat. In addition, the end surfaces 20c of the additional film 20C has stepped portions 20d.

FIG. 25 is an elevational cross-sectional view of an acoustic wave device according to a third preferred embodiment. In an acoustic wave device 31, an acoustic multilayer film 32 is laminated on the second principal surface 2b of the piezoelectric layer 2. The acoustic multilayer film 32 has a laminated structure of low acoustic impedance layers 32a, 32c, and 32e, whose acoustic impedance is relatively low, and high acoustic impedance layers 32b and 32d, whose acoustic impedance is relatively high. When the acoustic multilayer film 32 is used, without use of the air gap 9 of the acoustic wave device 1, primary thickness-shear mode bulk waves may be confined in the piezoelectric layer 2. Also in the acoustic wave device 31, d/p described above is to be equal to or less than about 0.5. Thus, resonance characteristics based on primary thickness-shear mode bulk waves may be obtained. In the acoustic multilayer film 32, the number of laminated layers of low acoustic impedance layers and high acoustic impedance layers is not particularly limited. Any structure may be employed as long as the acoustic multilayer film 32 has at least one low acoustic impedance layer and at least one high acoustic impedance layer.

The low acoustic impedance layers 32a, 32c, and 32e and the high acoustic impedance layers 32b and 32d may be made of appropriate materials as long as the relationship of acoustic impedance described above is satisfied. For example, as a material of the low acoustic impedance layers 32a, 32c, and 32e, for example, silicon oxide or silicon oxynitride may be used. As a material of the high acoustic impedance layers 32b and 32d, for example, alumina, silicon nitride, or a metal may be used.

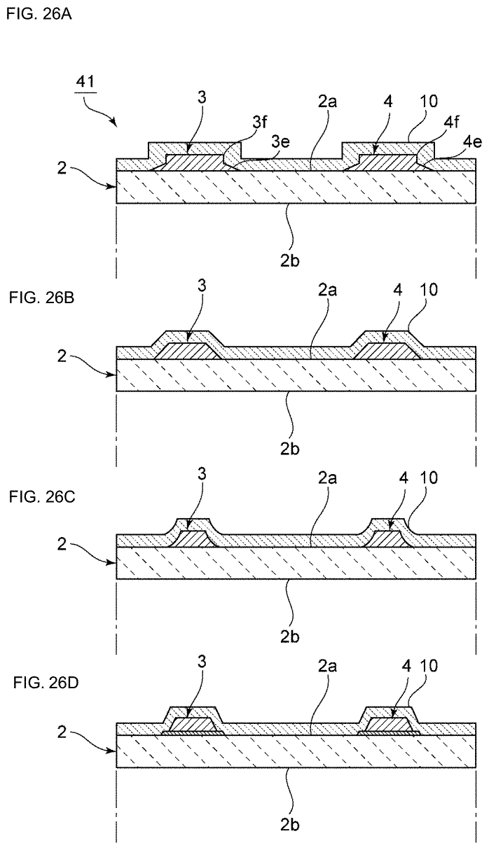

FIGS. 26A to 26D are elevational cross-sectional views for describing piezoelectric layers and single pairs of electrodes of acoustic wave devices according to a fourth preferred embodiment and its first to third modified examples. An acoustic wave device 41 according to the fourth preferred embodiment illustrated in FIG. 26A includes at least one pair of an electrode 3 and an electrode 4 each having a variant cross-sectional shape different from a rectangular shape. That is, the electrodes 3 and 4 include flared portions 3e and 4e, respectively, positioned on the first principal surface 2a, and also include rectangular cross-section portions 3f and 4f, respectively, disposed on the flared portions 3e and 4e. The flared portions 3e and 4e taper along their side surfaces so as to become thinner from the first principal surface 2a side toward the rectangular cross-section portions 3f and 4f, respectively. The distance between an electrode 3 and an electrode 4 may be made small due to the flared portions 3e and 4e which are disposed. Therefore, the capacitance between electrodes may be made large. Thus, the capacitance may be made large while the resonance characteristics are not changed by a large extent.

Thus, the cross section of at least one pair of an electrode 3 and an electrode 4 may have a shape different from a rectangular shape, that is, a variant shape. In addition, the electrodes 3 and 4 may have portions extending toward their paired electrodes 4 and 3, respectively.

The electrodes 3 and 4 may have a shape, for example, as illustrated in any of FIGS. 26B to 26D. In a first modified example of the fourth preferred embodiment illustrated in FIG. 26B, the cross section of the electrodes 3 and 4 is trapezoidal. In a second modified example illustrated in FIG. 26C, the electrodes 3 and 4 have a flared shape, and both the side surfaces in the width direction are curved. In a third modified example illustrated in FIG. 26D, the electrodes 3 and 4 each include a trapezoidal portion on the upper end side of the cross section illustrated in FIG. 26D. On the lower end side of the cross section, the electrodes 3 and 4 each include a trapezoidal portion having a width wider than that of the trapezoidal portion on the upper end side.

The acoustic wave devices according to preferred embodiments of the present invention may be used in a filter device such as a band pass filter. This example will be described below.

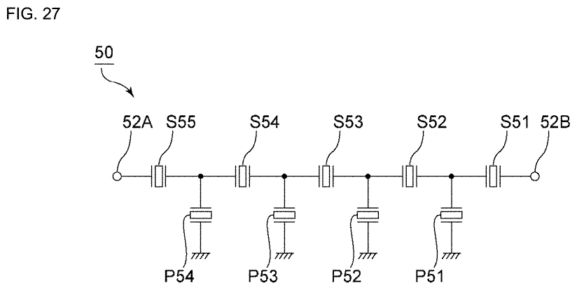

FIG. 27 is a circuit diagram of a filter device according to a fifth preferred embodiment. A filter device 50 according to the present preferred embodiment is a ladder filter. The filter device 50 includes a first signal end 52A, a second signal end 52B, multiple serial arm resonators, and multiple parallel arm resonators. In the present preferred embodiment, all the multiple serial arm resonators and multiple parallel arm resonators are acoustic wave devices according to preferred embodiments of the present invention. Any configuration may be used as long as at least one resonator among the multiple serial arm resonators and the multiple parallel arm resonators is an acoustic wave device according to one of the various preferred embodiments of the present invention. At least one serial arm resonator and at least one parallel arm resonator are preferably acoustic wave devices according to one of the various preferred embodiments of the present invention.

The first signal end 52A is an antenna end connected to an antenna. The first signal end 52A and the second signal end 52B may be electrode pads, or may be wires.

A specific circuit configuration of the filter device 50 is as follows. A serial arm resonator S51, a serial arm resonator S52, a serial arm resonator S53, a serial arm resonator S54, and a serial arm resonator S55 are connected to each other in series between the first signal end 52A and the second signal end 52B.

A parallel arm resonator P51 is connected between a connection point between the serial arm resonator S51 and the serial arm resonator S52, and the ground potential. A parallel arm resonator P52 is connected between a connection point between the serial arm resonator S52 and the serial arm resonator S53, and the ground potential. A parallel arm resonator P53 is connected between a connection point between the serial arm resonator S53 and the serial arm resonator S54, and the ground potential. A parallel arm resonator P54 is connected between a connection point between the serial arm resonator S54 and the serial arm resonator S55, and the ground potential. The circuit configuration illustrated in FIG. 27 is exemplary. The circuit configuration of the filter device 50 is not limited to that described above.

In the present preferred embodiment, the multiple serial arm resonators and the multiple parallel arm resonators are acoustic wave devices according to one of the various preferred embodiments of the present invention. Thus, even when the size is reduced, the Q value of each resonator may be improved. In addition, the frequency may be adjusted easily.

Each of the serial arm resonators and the parallel arm resonators includes an additional film according to a preferred embodiment of the present invention. The thickness of the additional films of the serial arm resonators is preferably different from the thickness of the additional films of the parallel arm resonators. This enables desired characteristics to be obtained easily through adjustment in each of the serial arm resonators and the parallel arm resonators. Thus, the filter characteristics may be adjusted suitably.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer made of lithium niobate or lithium tantalate;
a first electrode and a second electrode that face each other in a direction intersecting a thickness direction of the piezoelectric layer; and
an additional film located on the piezoelectric layer or on at least one of the first electrode or the second electrode so as to overlap, in plan view, at least one of a first area or a second area, the first area including areas in which the first electrode and the second electrode are located, the second area being an area between the first electrode and the second electrode; wherein
the acoustic wave device uses primary thickness-shear mode bulk waves.

2. The acoustic wave device according to claim 1, wherein each of the first electrode and the second electrode is an electrode connected to a first busbar or an electrode connected to a second busbar.

3. The acoustic wave device according to claim 1, wherein the first electrode and the second electrode have a lengthwise direction, and the first electrode faces the second electrode in a direction orthogonal to the lengthwise direction.

4. The acoustic wave device according to claim 1, wherein a thickness of the additional film is equal to or less than a thickness of each of the first electrode and the second electrode.

5. The acoustic wave device according to claim 1, wherein the additional film is provided on the piezoelectric layer so as to, at least, overlap, in plan view, the area between the first electrode and the second electrode.

6. The acoustic wave device according to claim 5, wherein the piezoelectric layer includes first and second principal surfaces which face each other;
the first electrode and the second electrode are provided on the first principal surface of the piezoelectric layer;
the additional film is located on the first principal surface of the piezoelectric layer, and the additional film covers the first electrode, the second electrode, and a portion, the portion being positioned between the first electrode and the second electrode on the first principal surface; and
a first portion of the additional film is thinner than a second portion of the additional film, the first portion being provided on the first electrode and the second electrode, the second portion being provided on the piezoelectric layer.

7. The acoustic wave device according to claim 5, wherein the additional film is provided on the piezoelectric layer so as to overlap, in plan view, only the area between the first electrode and the second electrode.

8. The acoustic wave device according to claim 1, wherein
the first electrode is adjacent to the second electrode; and
t/p×100(%) is equal to or less than about 0.83% where t represents a thickness of the additional film, and p represents a center-to-center distance between the first electrode and the second electrode.

9. The acoustic wave device according to claim 1, wherein
the additional film includes first and second surfaces and end surfaces, the first and second surfaces facing each other in a thickness direction of the additional film, the end surfaces connecting with the first surface and the second surface; and
the end surfaces extend at an inclination with respect to a direction in which the first surface faces the second surface.

10. The acoustic wave device according to claim 1, wherein the first electrode faces the second electrode on an identical principal surface of the piezoelectric layer.

11. An acoustic wave device comprising:
a piezoelectric layer made of lithium niobate or lithium tantalate;
a first electrode and a second electrode that face each other in a direction intersecting a thickness direction of the piezoelectric layer; and
an additional film located on the piezoelectric layer or on at least one of the first electrode or the second electrode so as to overlap, in plan view, at least one of a first area or a second area, the first area including areas in which the first electrode and the second electrode are located, the second area being an area between the first electrode and the second electrode; wherein
the first electrode is adjacent to the second electrode; and
d/p is equal to or less than about 0.5 where d represents a thickness of the piezoelectric layer, and p represents a center-to-center distance between the first electrode and the second electrode.

12. The acoustic wave device according to claim 11, wherein the d/p is equal to or less than about 0.24.

13. The acoustic wave device according to claim 11, wherein a metallization ratio MR satisfies an expression, MR≤1.75(d/p)+0.075, the metallization ratio MR being a ratio of an area of the first electrode and the second electrode in an excitation zone with respect to the excitation zone, the excitation zone corresponding to an area in which the first electrode overlaps the second electrode when viewed in a direction in which the first electrode faces the second electrode.

14. The acoustic wave device according to claim 11, wherein each of the first electrode and the second electrode is an electrode connected to a first busbar or an electrode connected to a second busbar.

15. The acoustic wave device according to claim 11, wherein the first electrode and the second electrode have a lengthwise direction, and the first electrode faces the second electrode in a direction orthogonal to the lengthwise direction.

16. The acoustic wave device according to claim 11, wherein a thickness of the additional film is equal to or less than a thickness of each of the first electrode and the second electrode.

17. The acoustic wave device according to claim 11, wherein the additional film is provided on the piezoelectric layer so as to, at least, overlap, in plan view, the area between the first electrode and the second electrode.

18. The acoustic wave device according to claim 17, wherein the piezoelectric layer includes first and second principal surfaces which face each other;
the first electrode and the second electrode are provided on the first principal surface of the piezoelectric layer;
the additional film is located on the first principal surface of the piezoelectric layer, and the additional film covers the first electrode, the second electrode, and a portion, the portion being positioned between the first electrode and the second electrode on the first principal surface; and
a first portion of the additional film is thinner than a second portion of the additional film, the first portion being provided on the first electrode and the second electrode, the second portion being provided on the piezoelectric layer.

19. The acoustic wave device according to claim 17, wherein the additional film is provided on the piezoelectric layer so as to overlap, in plan view, only the area between the first electrode and the second electrode.

20. The acoustic wave device according to claim 11, wherein
the first electrode is adjacent to the second electrode; and
t/p×100(%) is equal to or less than about 0.83% where t represents a thickness of the additional film, and p represents a center-to-center distance between the first electrode and the second electrode.

21. The acoustic wave device according to claim 11, wherein the additional film includes first and second surfaces and end surfaces, the first and second surfaces facing each other in a thickness direction of the additional film, the end surfaces connecting with the first surface and the second surface; and
the end surfaces extend at an inclination with respect to a direction in which the first surface faces the second surface.

22. The acoustic wave device according to claim 11, wherein the first electrode faces the second electrode on an identical principal surface of the piezoelectric layer.

23. A filter device comprising:
at least one serial arm resonator; and
at least one parallel arm resonator; wherein
at least one of the at least one serial arm resonator and at least one of the at least one parallel arm resonator are defined by the acoustic wave device according to claim 1; and
a thickness of the additional film of the at least one serial arm resonator is different from a thickness of the additional film of the at least one parallel arm resonator.

24. A filter device comprising:
at least one serial arm resonator; and
at least one parallel arm resonator; wherein
at least one of the at least one serial arm resonator and at least one of the at least one parallel arm resonator are defined by the acoustic wave device according to claim 11; and
a thickness of the additional film of the at least one serial arm resonator is different from a thickness of the additional film of the at least one parallel arm resonator.
